(19) United States
(12) Patent Application Publication
(10) Pub. No.: US 2009/0223549 A1
(43) Pub. Date: Sep. 10, 2009

(54) SOLAR CELL AND FABRICATION METHOD USING CRYSTALLINE SILICON BASED ON LOWER GRADE FEEDSTOCK MATERIALS

(75) Inventors: Kamel Ounadjela, Belmont, CA (US); Jean Patrice Rakotoniaina, Berlin (DE); Martin Kaes, Berlin (DE); Dirk Zickermann, Berlin (DE); Alain Blosse, Belmont, CA (US); Abdellatif Zerga, Berlin (DE); Matthias Heuer, Berlin (DE); Fritz Kirscht, Berlin (DE)

Correspondence Address: HULSEY IP INTELLECTUAL PROPERTY LAWYERS, P.C., 919 Congress Avenue, Suite 919, AUSTIN, TX, 78701, US

(73) Assignee: CaliSolar, Inc., Menlo Park, CA (US)

(21) Appl. No.: 12/045,259

(22) Filed: Mar. 10, 2008

(51) Int. Cl. H01L 31/042; H01L 31/00

(52) U.S. Cl. 136/244; 136/256

(57) ABSTRACT

Formation of a solar cell device from upgraded metallurgical grade silicon which has received at least one defect engineering process and including a low contact resistance electrical path. An anti-reflective coating is formed on an emitter layer and back contacts are formed on a back surface of the bulk silicon substrate. This photovoltaic device may be fired to form a back surface field at a temperature sufficiently low to avoid reversal of previous defect engineering processes. The process further forms openings in the anti-reflective coating and a low contact resistance metal layer, such as nickel layer, over the openings in the anti-reflective coating. The process may anneal the low contact resistance metal layer to form n-doped portion and complete an electrically conduct path to the n-doped layer. This low temperature metallization (e.g., <700° C.) supports the use of UMG silicon for the solar device formation without the risk of reversing earlier defect engineering processes.

### FIELD

The present invention relates generally to photovoltaic devices, and more particularly to a system and method for making an improved solar cell derived from crystalline silicon based on lower grade feedstock materials.

### DESCRIPTION OF THE RELATED ART

Photovoltaic solar cells directly convert radiant energy from the sun into electrical energy. Photovoltaic cells can be aligned as an array that aligns various numbers of cells to provide a greater output of electricity. This makes solar electricity a viable option to power small homes and businesses.

The manufacture of photovoltaic solar cells involves use of semiconductor substrates in the form of sheets or wafers having a shallow p-n junction adjacent one surface, commonly called the “front side.” The solar cell substrate may be of polycrystalline silicon having p-type conductivity and a p-n junction located about 0.3-0.5 microns from its front side, and having a silicon nitride coating approximately 80 nm (depending on the applied texturization and refractive index of the used coating) thick covering the front side.

In operation, solar radiation impinging on the solar cell creates electrons and holes that migrate to the p-doped and n-doped regions, thereby creating voltage differentials between the doped regions. The front side of the solar cell, wherein are connections to an external electrical circuit, may include several layers of materials between the metallic surface and the doped regions. These materials may be patterned and etched to form internal devices.

Solar cell wafers are converted to finished solar cells by providing metallization on both the front and back surfaces (i.e., the p- and n-junctions) of the semiconductor substrate, so as to permit recovery of the electrical current from the cells when they are exposed to solar radiation. These contacts are typically made of aluminum, silver, nickel or other metal or metal alloy. A common preferred arrangement is to provide silicon solar cells with back contacts made of aluminum and front contacts made of silver.

To improve the conversion efficiency of the cell, an anti-reflective coating (ARC) overlies and is bonded to those areas of the front side that are not covered by front side contacts. The back contact may cover the entire back surface of the solar cell wafer, but more commonly, it is formed so as to terminate close to but short of the edges of the solar cell.

One of the most exciting areas of development in today's solar cell fabrication industry relates to the use of the more abundant and economical use of upgraded metallurgical grade (UMG) silicon for solar cell bulk silicon regions. Using UMG silicon to achieve efficiently operating solar cells allows the costs of producing solar energy can begin to compete well in the energy markets against petroleum and other forms of energy. In using UMG or silicon feedstock, with similar quality additional process constraints may arise.

For example, in the formation of a solar cell, generally a firing process takes place that involves elevating the solar cell device temperature to approximately 800° C. or higher. This process seeks to achieve three distinct results. First of all, the process seeks to position front side contacts in contact with an n-doped emitter layer of the solar cell. Secondly, the process seeks to diffuse hydrogen from the ARC into the p-doped bulk silicon for defect passivation. And, lastly the process seeks to anneal the aluminum back surface of the solar cell device with the p-doped bulk silicon for establish a more heavily p-doped region called BSF (Back Surface Field) which repulse the electrons towards the p-n junction.

Although achieving all three results is desired, generally these results occur partially within a very narrow process window. That is, these three heat-responsive processes require different temperature ranges and heating durations. As such, it is generally not practical or optimal to achieve the desired results with a single process.

In particular forming the front side contacts requires a high temperature process (e.g., approximately 800° C.) for a short duration (e.g., 10 seconds). If the temperature process is not adjusted correctly, high serial resistance and/or low shunt resistance will result. This occurs for several physical reasons. Reasons may include metal penetration into the bulk silicon, poor formation of Ag crystallites in the n-doped region and/or poor intergrowth of these Ag crystallites with the Ag fingers. These undesirable phenomena are known as over-firing or under-firing phenomena.

Conversely, annealing the aluminum back surface layer with the p-doped bulk silicon can be achieved already at lower temperatures. The eutectic temperature of the Al—Si binary system is the minimum temperature needed. According to the liquidus/solidus curve of an Al/Si alloy, however, a higher temperature gives an increased Al doping and, therefore, a more efficient back surface field (BSF). If the temperature is too high (e.g., >850° C.), the BSF quality generally decreases, principally due to inhomogeneity problems, and wafer bowing can become critical. While there may be Al pastes that allow higher firing temperatures, even with these improvements, the duration at such temperature can only be in the range of several seconds.

Because of the conflicting temperature and duration limitations, forming a solar cell using a single firing process generally yields a sub-optimally performing device. At the same time, using two firing processes yet results in an ineffective solar cell.

Another limitation of known solar cell formation processes relates to the use of firing processes with solar cells using UMG silicon. In order to use UMG silicon, however, novel defect engineering processes are required. Frequently, effective defect engineering requires the use of heat-activated processes, such as gettering and annealing processes that promote the localization or otherwise minimizing the effects of impurities and defects. These gettering and annealing processes are carefully controlled to occur at temperatures around 800° C. Once such processes have been completed, it is highly desirable that a solar cell using such defect engineered silicon not be further heated above these temperatures for an extended period. This is so, because doing so may reverse or adversely affect the defect engineering results.

There is a need, therefore, for a process to form solar cells on crystalline silicon based on lower grade feedstock materials that avoids high temperature process steps after the emitter formation. Such a process will eliminates or substantially reduces the described temperature-duration misalignment that exists with known solar cell fabrication processes.

Alternatively, a tailored time-temperature budget is provided in case of applying additional defect engineering for material improvement such as hydrogenation. In such a case high temperatures are allowed to exist for only very short times (e.g., at maximum several seconds). The higher the temperature may be, the shorter will be the duration of such temperatures. As such, a beneficial trade-off time and temperature steps may be considered. For instance, a different back surface passivation (dielectric layer) may help decreasing optimal temperature for hydrogenation and back surface metallization.

Additionally, there is the need for an improved solar cell metallization process that forms the more heavily p-doped aluminum-silicon solar cell layer at temperatures below those likely to affect previously successful UMG silicon defect engineering processes.

A need yet exists for a solar cell formation process that provides for hydrogen passivation of bulk silicon defects and back surface field formation at temperatures below those that may risk defect engineering reversal, and yet provide for the formation of front side solar cell metallization.

### SUMMARY

Techniques are here disclosed to form solar cells on crystalline silicon based on lower grade feedstock materials. These techniques use tailored thermal budgets in the course of cell processing. This leads to more efficient, and economical production of solar cell devices, especially at using defect-engineered UMG silicon wafers.

According to one aspect of the disclosed subject matter, a method or process for forming a low contact resistance solar cell and the resulting solar cell are disclosed. The solar cell may be achieved on a bulk silicon substrate comprising UMG or other low grade feedstock-silicon, as well as higher grade silicon for which the lower resistance properties here disclosed may be beneficial.

The solar cell includes forming an emitter layer on the bulk silicon substrate, such as a phosphorus-based emitter formation process and removing a substantial portion of any phosphorus glass arising from the emitter layer forming step. The process further forms an anti-reflective coating on the emitter layer and a plurality of back contacts on a back surface of the bulk silicon substrate to yield a photovoltaic device that ultimately yields a solar cell through the process here described. Firing the photovoltaic device then occurs for forming a back surface field using a time-temperature budget that is sufficiently low to avoid reversal of the results earlier achieved through one or more defect engineering processes. Then, the process includes isolating edges of the photovoltaic device for reducing edge shunts of the photovoltaic device and further forming a plurality of openings in the anti-reflective coating for at least partially exposing an n-doped portion of the emitter layer.

The process includes coating of the opened regions of the anti-reflective layer with a low contact resistance metal layer, such as electroless selective nickel. The process further anneals the electroless selective nickel layer with the n-doped portion for forming a nickel-silicide layer and electroplates a plurality of contacts on the nickel-silicide layer, thereby forming a low resistance contact path for the photovoltaic device.

According to one aspect, the disclosed method includes a firing step that may occur at a process temperature generally below 700° C., thereby preserving the effects of previous defect engineering process for the lower grade crystalline silicon.

Another aspect of the present disclosure, alternatively, includes a short temperature anneal in the range >800° C., at least for hydrogenation. Such a step may be decoupled from the front side metallization (plating) to provide the additional advantage of resulting in a more reliable front contact with less spreading.

According to a still further aspect, the anti-reflective coating may be formed based on a dielectric material, such as silicon nitride, carbo-nitrides or carbo-oxy-nitrides.

Another aspect of the present disclosure includes electroplating a plurality of metals, such as copper or similarly useful metal, as contacts on the metal silicides such as nickel silicide layers.

These and other advantages and aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features, and advantages here provided will become apparent to one with skill in the art upon examination of the following FIGUREs and detailed description. It is intended that all such additional systems, methods, features and advantages be included within this description, be within the scope of the accompanying claims.

### BRIEF DESCRIPTIONS OF THE DRAWINGS

The present invention will now be described in detail with reference to the drawings, which are provided as illustrative examples of the invention so as to enable those skilled in the art to practice the invention. Notably, the figures and examples are not meant to limit the scope of the present invention to a single embodiment, but other embodiments are possible by way of interchange of some or all of the described or illustrated elements and, further, wherein:

FIG. 1 shows a process flow for the presently disclosed subject matter including the formation of a low resistance metallization for a photovoltaic device; and

FIGS. 2 through 12 present conceptual diagrams depicting a cross-section of a photovoltaic device, and ultimately a solar cell, employing the teachings of the present disclosure according to the process flow of FIG. 1.

### DETAILED DESCRIPTION OF THE SPECIFIC EMBODIMENTS

In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

The method and system of the present disclosure provide a method for forming a low resistance metallization in the formation of a solar cell. Although the present disclosure has particular application in solar cells formed using UMG silicon, it should be understood that the present disclosure may further apply to any form of silicon, including float zone silicon, Czochralski silicon, magnetic Czochralski silicon, cast silicon, and sheet or ribbon silicon.

Preferably, the minority carrier diffusion length under operating cell conditions will exceed the cell thickness. Yet, there may be other materials with smaller diffusion lengths (e.g., RGS, as well as highly doped UMG material) that may demonstrate advantageous properties for the purposes of the present disclosure. In fact, there may be only a small percentage of multi-crystalline silicon material demonstrating a homogeneous distributed diffusion length exceeding the cell thickness within the complete cell area. So, consideration of this should be made in material selection.

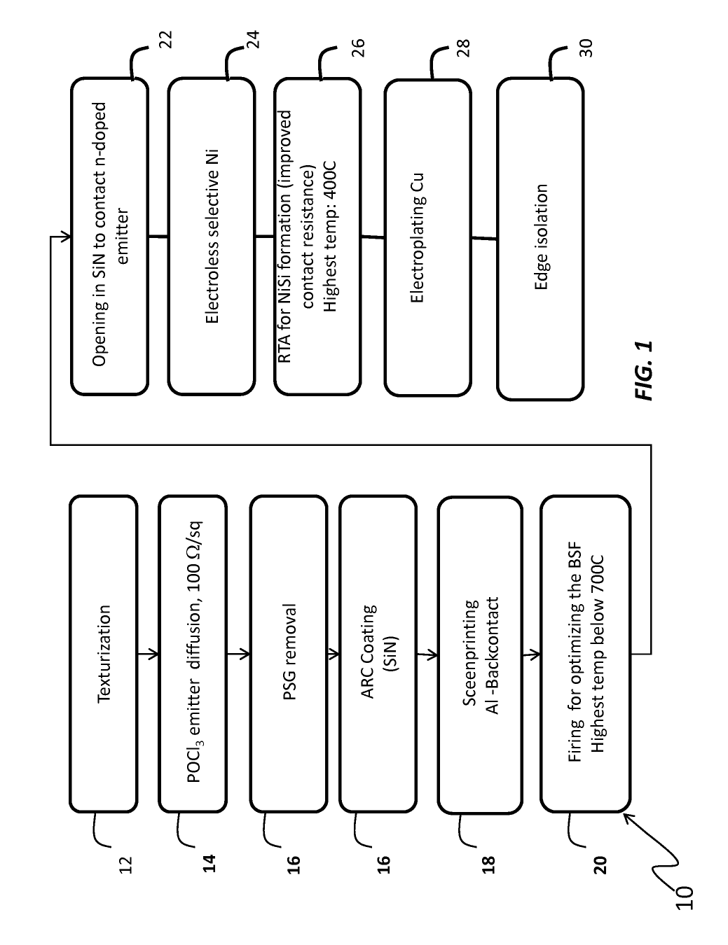

FIG. 1 shows process flow 10 for the presently disclosed subject matter resulting in the formation of a solar cell derived from lower grade crystalline silicon. Beginning at step 12, a texturization step occurs for creating a texture on the surfaces of the silicon substrate that is conducive to solar cell layer formation. This is followed, at step 14, with, for example, a POCL₃ or other phosphorous-based emitter forming an emitter layer having a sheet resistance for producing, in one embodiment, a sheet resistance of approximately 100 Ω/sq which is generally considered to be adequate for surface passivation. Note, however, that other diffusion techniques, e.g. spray-on diffusion may also be used to achieve essentially similar results at this point. Following emitter layer formation, any PSG (phospho-silicate glass) formed from the high-temperature emitter diffusion step is then removed at step 16. The process then applies an anti-reflective (AR) coating at step 18. Step 20 presents the step of screen-printing a layer consisting at least in part of aluminum (Al) on the back surface the silicon substrate from which a back surface field layer may be formed, as well as contacts for the photovoltaic device.

Step 20 introduces a novel aspect of the present disclosure of firing the photovoltaic device for forming and optimizing the back surface field, applying the time-temperature budget of the present disclosure. Then follows an edge isolation step 22 and the formation, at step 24, of openings in top side silicon nitride layer form. These opening for a connection path to the n-doped emitter layer below. Step 26 presents the step of forming an electroless selective nickel (Ni) layer over the silicon nitride layer and into the now formed openings. A rapid thermal anneal (RTA) step 28 then follows to form a nickel silicide improved connection path to the emitter layer, yet at a temperature below approximately 420° C. Note, however, that even at such temperatures, process time should be kept as short as possible to prevent de-hydrogenation from occurring within the substrate. The disclosed process further includes electroplating copper or another metal with similar properties for completing the front side metallization path for the photovoltaic device.

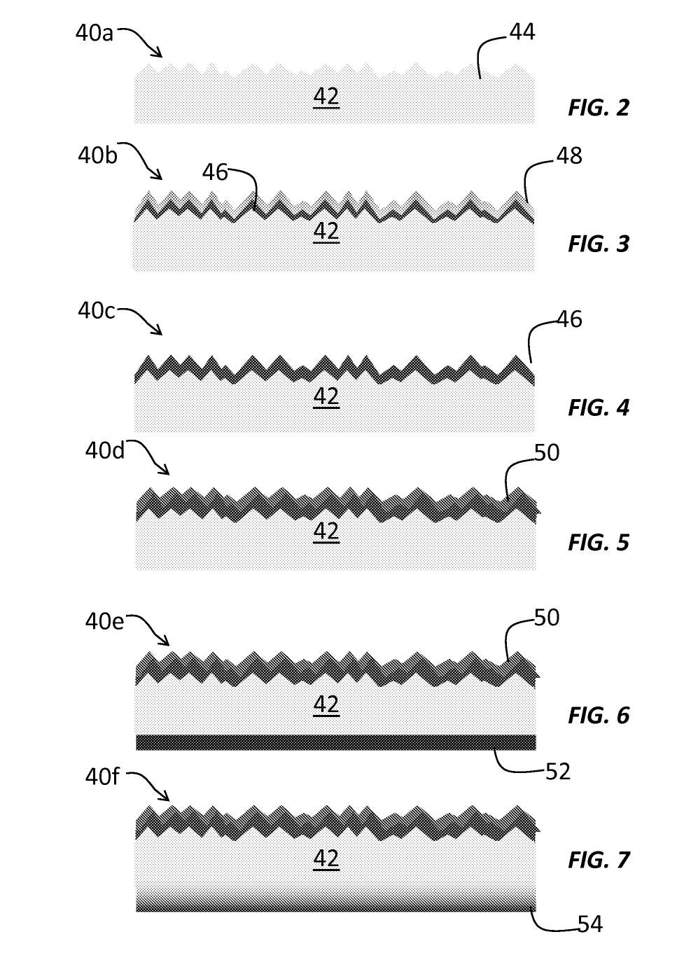

Having introduced process flow 10 for forming the improved solar cell with the low resistance metallization, FIGS. 2 through 12 present conceptual cross-sections forming the desired solar cell, here referred to progressively using reference numerals 40a through 40j to refer to the intermediate result of a “photovoltaic device” and ultimately at FIG. 12 as solar cell 40k.

Referring to FIG. 2, silicon substrate 42 shows on front side 44 the results of texturization step 12. Surface texturing of both top and bottom surfaces is provided in order to trap more incident light. However, in some embodiments, bottom texturing may be not desired. If bottom texturing is not desired, the bottom could be kept flat by use of appropriate texturization technique. These techniques may include, for example, using an anti-etching paste deposited by screen printing process on the back surface. Such surface texturing as is shown in the form of a saw-tooth pattern, which may be introduced mechanically by sawing or optically such as by laser etching. Though in the preferred embodiment texturing and doped surfaces are shown, their use is optional in the general case.

FIG. 3 depicts the results of POCL₃ emitter diffusion step 14 forming an emitter layer, wherein both the emitter layer 46 and PSG glass 48 form on photovoltaic device 40b. The emitter could be realized by a diffusion process using, for instance, POCL₃ between 800 and 900° C. in a tube furnace. This could lead to a sheet resistance of approximately 100 Ω/sq, in contrast to the typical 40 Ω/sq arising from conventional processes. The presently disclosed process forms an emitter with a sheet resistance of 100 Ω/sq. Because of the higher sheet resistance, less phosphorus exists in the emitter layer. This results in fewer recombination centers in the emitter, in conjunction with a low resistance metallization path.

At 800° C., it may be desirable to diffuse a very shallow emitter, while at 900° C., the process may include forming an emitter dotted with low sheet resistance. In some embodiments, a process temperature range of between 820 and 860° C. may achieve all or at least a majority of the process objectives.

Emitter layer 46 may be formed by application of a phosphorus source to wafers and thermal diffusion. The source can be applied by commercial techniques such as screen printing, spray-on, spin-on or POCl₃. The phosphorus diffusion can be carried out as a batch process in a tube furnace, as a continuous process in a belt furnace or by rapid thermal processing (RTP). A belt furnace can be heated by either infrared (IR) lamps or resistance heating (muffle type furnace). FIG. 4 shows the result of PSG glass 48 removal, leaving only emitter layer 46 on photovoltaic device 40c. During the POCL₃ emitter diffusion, a Phosphorus silicate glass is formed. The PSG layer is removed to continue the process using wet or dry chemical etch.

FIG. 5 presents the formation of ARC 50 on photovoltaic device 40d. ARC 50 is mainly transparent to solar radiation and is often made of silicon nitride or an oxide of silicon or titanium applied by plasma-enhanced chemical vapor deposition (PECVD) or titanium dioxide applied by atmospheric pressure chemical vapor deposition (APCVD) can be used. Hydrogen ion implantation to improve minority carrier diffusion length may also be introduced prior to an ARC deposition. However, if the process uses SiN or SiCN, the hydrogen implantation may not be required.

FIG. 6 presents the result of screen printing Al layer 52 on the back surface of silicon substrate 42 from which a back surface field layer 54 may be formed, as well as contacts for the photovoltaic device 40e. Generally, Al layer 52 of p-type material is relatively thin when compared to the p-type bulk layer, about 2 to 20 μm thick for a bulk layer with thickness of about 200 μm. A preferred method for depositing aluminum is to deposit by screen printing the aluminum, a process known per se in the art, in an aluminum paste. However, methods other than screen-printing for depositing the aluminum are within the scope of the invention, such as electron beam evaporation or sputtering, although these methods may require more costly patterning by photolithography and so are less desirable. Aluminum or aluminum material herein is defined as either pure Al or an Al—Si alloy.

Note that in a preferred embodiment, the choice of aluminum serves at least three purposes simultaneously. Aluminum acts as a p-type dopant source to compensate the n-dopant on the rear side, while also acting as a back surface reflector for the electrons. Aluminum also serves as electrical contact in the p-type region.

FIG. 7 shows the results of firing the photovoltaic device 40f for forming and optimizing the back surface field, yet at a highest temperature of less than approximately 700° C. This produces back surface field region 54, which is more heavily p-doped than bulk silicon region 42.

Firing for optimizing the back surface field occurs at a highest temperature below 700° C. Firing happens at this step. Generally, there is no need to have a high temperature process, since making a reasonable back surface field layer requires less than 700° C. A rapid thermal processing unit, a belt furnace, a tube furnace, or other means may provide heating. The ambient atmosphere can be inert, such as argon or nitrogen, or chemically active such as with oxygen or hydrogen. Mixtures of ambient gases are also possible. Times at elevated temperatures can range from 30 seconds to several minutes.

Process temperature may then be lowered in the Si—Al alloy, and Si regroups by liquid phase epitaxy until the eutectic temperature (577° C.) is reached. As a result, the regrown Si is now doped p-type with Al. The required p-type is formed as the Al concentration exceeds the donor concentration in the starting Si, and the eutectic alloy (about 88.7% Al and 11.3% Si, by weight) remains on the surface to serve as stripe contacts to the p-type silicon.

The depth of the alloy junction can be controlled by using an Al—Si mixture as the screen-printed material deposited, instead of pure Al. This is because as the Si concentration is increased toward the eutectic composition, the amount of Si that the printed metal can dissolve becomes less, hence the junction depth becomes smaller. The junction depth can be increased, if desired, by increasing the thickness of the deposited aluminum and by increasing the alloying temperature, in accordance with the aluminum-silicon phase diagram.

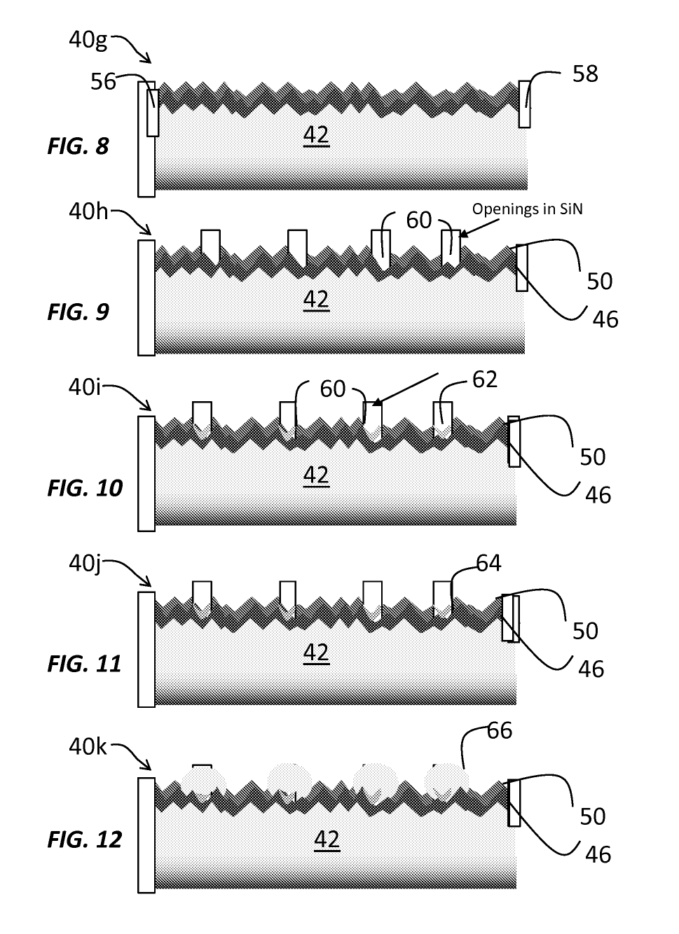

FIG. 8 presents in photovoltaic device 40g the edge isolations 56 and 58 formed with edge isolation step 22. However, ARC 50 and emitter layer 46 may coat the entire wafer, including the edges, and often the back surface, creating an unacceptable recombination pathway between the front and back surfaces. This pathway can be eliminated by edge isolation, whereby a groove is continuously scribed completely through the n-type emitter layer 46. In order to maximize the photovoltaic device 40g active area, and hence efficiency, this groove preferably should be as narrow and as close to the edge as possible. Other techniques may be applied as well. For example, one process may include removing the n-doped region between front side and the aluminum back surface field. This may occur either by partially removing the n-doped region (dry etching at the border) or completely removing the n-doped region at the back surface (with wet or dry chemicals).

FIG. 9 shows in photovoltaic device 40h openings 60 through ARC 50 forming connection paths to the n-doped emitter layer 46. These openings may be formed by patterning techniques such as: laser ablation, lithography, screen printing, ink jet, and other similarly effective techniques. Such patterning techniques should be very selective to the emitter.

FIG. 10 presents electroless selective metal deposition such as nickel (Ni) layer 62 formed over openings 60 of photovoltaic device 40i. An electroless metal layer such as a Ni is then formed in the metallization formation process. This is a process that is very well known in the industry and appreciated, because of the high selectivity of nickel to silicon.

In FIG. 11, the rapid thermal anneal (RTA) step 28 then follows to form, for instance, nickel silicide connection path 64 from the front side of photovoltaic device 40j to emitter layer 46, below, and yet at a temperature below approximately 400° C. The rapid thermal anneal (RTA) process for NiSi layer formation further improves contact resistance to approach 0.1 Ω-cm².

Lastly, FIG. 12 presents low-resistance electroplated metal such as copper contacts completing the metallization path for the solar cell 40k. Then, the disclosed process applies an electroplating of copper.

A technical advantage of the present disclosure, therefore, is a process to form a solar cell metallization that eliminates or substantially increases the temperature-process window that exists with known solar cell fabrication processes.

Furthermore, the present disclosure provides an improved solar cell metallization fabrication process that forms the more heavily p-doped aluminum-silicon solar cell layer at temperatures below those likely to affect adversely previously successful UMG silicon defect engineering processes.

Still further, the disclosed subject matter provides a solar cell metallization formation process that includes hydrogen passivation of bulk silicon defects and back surface field formation at temperatures below those that may risk defect-engineering reversal, and while providing for the formation of front side solar cell metallizations.

In summary, thus, a novel aspect of the present disclosure is providing a solar cell process for crystalline silicon based on lower grade feedstock material. An emitter layer is formed using a phosphorus-based emitter formation process. An anti-reflective coating is formed on the emitter layer and back contacts on a back surface of the bulk silicon substrate. The device is then fired to form a back surface field at a temperature sufficiently low to avoid reversal of any previous defect engineering process. The process further forms openings in the anti-reflective coating for at least partially exposing an n-doped portion of said emitter layer. The process then forms an electroless selective nickel layer over the anti-reflective coating and through the opening for associating with an n-doped portion of the substrate. The process then anneals the electro less selective nickel layer with the n-doped portion for forming a nickel-silicon layer and further electroplates contacts on the nickel-silicon layer, completing an electrically conduct path from the contacts to the n-doped layer.

The process and system features and functions described herein, therefore, form a low resistance solar cell metallization and metallization formation method. Stepping back a bit, photovoltaic or solar cells, formed consistent with the teachings of the present disclosure may be aligned as an array with various panels fitted along a mounting system. One of the main advantages is the ability of such an array includes the ability to combine various numbers of cells to provide a greater output of electricity. This makes solar electricity a viable option to power small homes and businesses.

With the cost advantages of using UMG silicon, as here described, the increasing efficiency of solar energy technologies, it is possible to purchase and install panel harnessing energy from the sun's rays. The costs involved with supplying electricity from a solar array using the teaching here disclosed may provide a substantial amount of electricity, reducing future electricity generation costs and consumer energy expenditures.

Although various embodiments that incorporate the teachings of the present disclosure have been shown and described in detail herein, those skilled in the art may readily devise many other varied embodiments that still incorporate these teachings. The foregoing description of the preferred embodiments, therefore, is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein, but is to be accorded the widest scope consistent with the principles and novel features disclosed herein.

What is claimed is:

1. A method for forming a solar cell including a low resistance metallization layer, said solar cell comprising upgraded metallurgical grade silicon, the method comprising the steps of:
forming a bulk silicon substrate comprising upgraded metallurgical grade silicon, said upgraded metallurgical grade silicon having received at least one defect engineering process;
forming an emitter layer on said bulk silicon substrate using a phosphorus-based emitter formation process;
removing a substantial portion of any phosphorus glass arising from said emitter layer forming step;
forming an anti-reflective coating on said emitter layer;
forming a back contact region on a back surface of said bulk silicon substrate to yield a photovoltaic device;
firing said photovoltaic device for forming a back surface field at a temperature sufficiently low to avoid reversal of said at least one defect engineering process;
isolating edges of said photovoltaic device for reducing edge shunts of said photovoltaic device;
forming at least one opening in said anti-reflective coating for at least partially exposing an n-doped portion of said emitter layer;
coating said at least one opening with a low contact resistance metal layer; and
electroplating a plurality of metal contacts on said low contact resistance metal layer, thereby forming a low resistance contact path for transforming said photovoltaic device into a solar cell comprising upgraded metallurgical grade silicon.

2. The method of claim 1, wherein said low contact resistance metal layer further comprises an electroless selective nickel layer, and further comprising the step of annealing said electroless selective nickel layer for forming a nickel-silicide layer,

3. The method of claim 2, wherein said annealing step further comprises a rapid thermal annealing (RTA) step occurring at a process temperature generally below 400° C.

4. The method of claim 1, further comprising the step of forming said at least one opening in said anti-reflective coating in a pattern at least approximately conforming to the pattern of a metallization mask.

5. The method of claim 1, wherein said firing step occurs at a process temperature generally below 700° C.

6. The method of claim 1, wherein said anti-reflective coating step comprises forming a silicon nitride (SiN) layer on said emitter layer.

7. The method of claim 1, wherein said anti-reflective coating step comprises forming a silicon carbonitride (SiCN) layer on said emitter layer.

8. The method of claim 1, wherein said electroplating step further comprises the step of electroplating a plurality of copper contacts on said nickel-silicon layer.

9. The method of claim 1, further comprising the step of texturizing said bulk silicon substrate in preparation for said emitter layer forming step.

10. A low contact resistance solar cell using upgraded metallurgical grade silicon, said solar cell comprising:
a bulk silicon substrate comprising upgraded metallurgical grade silicon, said upgraded metallurgical grade silicon having received at least one defect engineering process
an emitter layer on said bulk silicon substrate formed using a phosphorus-based emitter formation process;
an anti-reflective coating on said emitter layer;
a back contact region formed on a back surface of said bulk silicon substrate;
a back surface field formed from firing said back contact region at a temperature sufficiently low to avoid reversal of said at least one defect engineering process;
at least one openings in said anti-reflective coating for at least partially exposing said emitter layer;
a low contact resistance metal layer coating said anti-reflective coating for associating with said at least partially exposed emitter layer;
said low contact resistance metal layer comprising an n-doped portion; and
a plurality of contacts electroplated on said low contact resistance metal layer for conducting electric current from said low contact resistance solar cell.

11. The low contact resistance solar cell of claim 10, wherein said metallization is formed in a process temperature generally below 700° C.

12. The low contact resistance solar cell of claim 10, wherein said metallization is formed using rapid thermal annealing (RTA) step occurring at a process temperature generally below 400° C.

13. The low contact resistance solar cell of claim 10, wherein said anti-reflective coating step comprises a silicon nitride (SiN) on said emitter layer.

14. The low contact resistance solar cell of claim 10, wherein said anti-reflective coating comprises a silicon carbonitride (SiCN) on said emitter layer.

15. The low contact resistance solar cell of claim 10, further comprising a plurality of copper contacts on said nickel-silicon layer.

16. A solar cell array comprising a plurality of low contact resistance solar cells at least of portion using upgraded metallurgical grade silicon, said solar cells comprising:
a bulk silicon substrate comprising upgraded metallurgical grade silicon, said upgraded metallurgical grade silicon having received at least one defect engineering process;
an emitter layer on said bulk silicon substrate formed using a phosphorus-based emitter formation process;
an anti-reflective coating on said emitter layer;
a back contact region formed on a back surface of said bulk silicon substrate;
a back surface field formed from firing said back contact region at a temperature sufficiently low to avoid reversal of said at least one defect engineering process;
at least one openings in said anti-reflective coating for at least partially exposing said emitter layer;
a low contact resistance metal layer coating said anti-reflective coating for associating with said at least partially exposed emitter layer;
said low contact resistance metal layer comprising an n-doped portion; and
a plurality of contacts electroplated on said low contact resistance metal layer for conducting electric current from said low contact resistance solar cell.

17. The solar cell array of claim 16, wherein said solar cell further comprises a back surface field is formed from firing said back contact region at a temperature generally below 700° C. to avoid reversal of said at least one defect engineering process.

18. The solar cell array of claim 16, wherein said low contact resistance metal layer further comprises an electroless selective nickel layer, and further comprising nickel-silicide layer formed by annealing said electroless selective nickel layer.

19. The solar cell array of claim 17, wherein said nickel-silicide layer is formed using a rapid thermal annealing (RTA) step occurring at a process temperature generally below 400° C.

20. The solar cell array of claim 16, wherein said anti-reflective coating comprises a silicon nitride (SiN) on said emitter layer.

21. The solar cell array of claim 16, wherein said anti-reflective coating comprises a silicon carbonitride (SiCN) emitter layer.

22. The solar cell array of claim 16, further comprising a plurality of copper contacts on said nickel-silicon layer.

23. The solar cell array of claim 16, further comprising a texturized front side of said bulk silicon substrate formed in preparation for said emitter layer forming step.
